(19) United States
(12) Patent Application Publication
(10) Pub. No.: US 2016/0061904 A1
(43) Pub. Date: Mar. 3, 2016

(54) Analysing Effects of Programs on Mobile Devices

(71) Applicant: BIZ2MOBILE LIMITED, Abingdon (GB)

(72) Inventor: Anton Jakob Flügge, Oxford (GB)

(21) Appl. No.: 14/836,001

(22) Filed: Aug. 26, 2015

(30) Foreign Application Priority Data
Aug. 26, 2014 (GB) 1415081.7

(51) Int. Cl. G01R 31/36

(52) U.S. Cl. CPC G01R 31/3651; G01R 31/3658

(57) ABSTRACT

A method for analysing the effect of installed applications (A1-An) on battery usage of mobile communications devices (D1-Dm). Each device has monitoring software which monitors battery usage at frequent intervals throughout the day. The monitoring software calculates the average battery discharge and at less frequent intervals, such as once a day, communicates remotely to a server (105) the details of which applications are installed on the device and the details of the state of the battery. Using data from many devices, the server estimates the effect of each application on battery usage. The estimated effects of the applications are updated each time that a further report is received, by revising the existing estimate. Greater weight is given to new data if the effect on battery usage has been consistently over- or under-estimated. It is not necessary to determine whether a particular application has been used on a device. The effect of all applications installed on a device is taken into account jointly. The effect on properties other than battery usage can be determined using this method.

### FIELD OF THE INVENTION

This invention relates to analysing the effect of programs on mobile data processing devices such as mobile telephones, tablet computers and other mobile devices. Embodiments of the invention are particularly concerned with programs which affect the performance of a mobile device, such as increasing battery usage, causing the device to crash and causing other disruptions. However, the invention is also relevant to analysing other effects such as those which, whilst not in themselves being disruptive to device performance, may indicate indirectly that there could be an effect on performance. The invention is applicable to all categories of programs including the operating system for the device as well as any applications installed on the device.

### BACKGROUND TO THE INVENTION

One particular effect that some embodiments of the invention analyse, is the battery performance. Certain applications installed on a device may cause abnormally high battery usage. Similarly, an update to the operating system of a device may have a deleterious effect on battery usage.

The energy usage of devices such as mobile telephones and tablet computers is frequently perceived to be excessively high. On many occasions, this is due to applications on the device which cause excessive battery drain when running. This can be a particular problem when the device is used in a business context, such as by delivery drivers, repair personnel and other users who are out of a workplace for lengthy period and who need to use the device regularly such as by noting deliveries of parcels or maintaining contact with people. Failure of a device because of a flat battery can have a serious effect on business operations.

In a paper “Carat: Collaborative Energy Diagnosis for Mobile Devices”, SenSys' 13, Nov. 11-15, 2013, Rome, Italy, authors Oliner, Iyer, Stoica, Lagerspetz and Tarkoma, there is disclosed a system which aims to detect abnormally high energy use. A client application on the device sends intermittent measurements to a server about:
The battery level fraction.
Whether the charger is plugged in or not.
The names of running processes.
Memory usage.
The operating system and version.
The device model.
A unique identifier for the device.

The server aggregates data from a community of many thousands of devices. Measurements are aggregated and the system compares average battery discharge rates under different conditions, such as which third party applications are running. The intention is to account, statistically, for individual variations in configurations and usage, and to determine whether energy usage is normal. The system builds and compares conditional probability distributions of rates of energy use to look for energy anomalies. As of the date of this application, Carat™ is available as an application for downloading onto iOS™ and Android™ mobile devices.

### SUMMARY OF THE INVENTION

One object of embodiments of the present invention is to provide an improved method in which the effect of programs on a property of a mobile device (such as battery life) is estimated by aggregating information from a community of mobile devices using machine learning and statistics, which is particularly useful in a business context.

According to one aspect of the invention, there is provided a method of analysing the effect of programs on a property of a plurality of mobile data processing devices, wherein:

on each of those mobile devices there is installed a monitoring application which (i) analyses events relating to a property of the device (ii) determines the programs installed on the device and (iii) at intervals transmits to a server monitoring data which includes identifiers identifying programs installed on the device, and information concerning the property of the device;

on the server, the monitoring data from the plurality of devices is aggregated and estimates are obtained of the contribution of each program to the effect on the property of the devices;

subsequent monitoring data from the plurality of devices is aggregated and revised estimates are obtained, by machine learning techniques, of the contribution of each program to the effect on the property of the devices;

wherein

when revising an existing estimate of the contribution of a program to the effect on the property of the devices, new data is used to revise the existing estimate rather than being combined with past data and the combined data being used to create a revised estimate.

Thus, when a new observation is received by the server concerning the effect on the property of a particular device and a revised estimate is obtained of the contribution of each program to the effect on the property of the devices, all past observations are not used equally, but instead the last estimate is updated by the new observation.

In accordance with this aspect of the invention, it is possible to detect changes very quickly. This generally gives more weight to more recent observations; old observations contribute to the current estimate only in so far as they have shaped the last estimate. As more time passes, and more new observations have been used to update the estimate in between, the influence of observations in the more distance past vanishes. For the Carat system referred to above, it does not matter in which order observations are collected, and all of them contribute equally.

For example, in the case of a property which is battery discharge, this aspect of the invention does not assume that the battery consumption of a given application under given circumstances (such as the, device model, whether wireless networking is turned on or off) will never change. This aspect of the invention is geared to very quickly detect changes in battery usage. In addition to just learning the average battery consumption of applications this allows this aspect of the invention to alert the user of the system if there is a sudden surge in battery consumption of one of the applications, which could indicate that there are problems that need attention.

In some embodiments of the invention, when revising an existing estimate of the contribution of a program to the effect on the property of the devices, an adaptive learning rate is used to determine how much weight to give new data relative to an existing estimate of the contribution of a program to the effect on the property of the device, so that the learning rate is increased if it has been determined that the effect of the property of the devices has been consistently under-estimated or over-estimated in the past.

In some embodiments of the invention, when revising an existing estimate of the contribution of a program to the effect on the property of the devices, the weight given to new data is adapted so that greater weight is given to new data if it has been determined that the effect of the property of the device has been consistently under-estimated or over-estimated in the past.

In some embodiments of the invention concerning, for example, battery usage an adaptive learning rate is used to determine how much weight to give the current observation relative to the last estimate when there is computed a new estimate. The learning rate is increased and/or more weight is given to the most recent observation, when there has been consistent over- or under-estimation of the battery discharge for last few observations. The more consistently wrong the estimate has been, the less weight is given to the previous estimate(s) when computing the new estimate.

In some embodiments of the invention, when estimating the contribution of a program to the effect on the property of the devices, data is received and processed in respect of applications installed on a device, irrespective of the usage there has been of those applications on that device.

In some embodiments of the invention, when estimating the contribution of a program to the effect on the property of the devices, the estimated contribution to the effect on the property of a particular device of all applications installed on that device is taken into account jointly.

In the Carat system referred to above, application usage is analysed, whereas this aspect of the invention does not take usage into account but computes—for example—the average battery usage on the devices an application is installed on. Related to that, is that the Carat system only compares situations where a particular application is used to those where an application is not used, but does not consider if other applications are running at the same time. Embodiments of the present invention explicitly considers all the applications installed on a device together and models what their joint impact on the battery usage is. Embodiments of the invention explicitly model and try to disentangle the effect of multiple applications being installed or run together. This for example provides better results if an application itself is not using much battery, but is typically run by power users who use many applications and consequently use a lot of battery.

It will be appreciated that the various features described above of embodiments of the invention can be used together in any combination or separately.

In an embodiments of the invention in which battery usage is analysed, some embodiments consider all applications installed on a device together by using estimates of the battery discharge of each application to predict the total battery discharge of a device with all of them installed. This predicted battery discharge can then be compared to the observed battery discharge of the device to determine if on average the system has over- or under-estimated the battery use of the different applications installed on the device and this can then be used to update other estimates. If a first application with low battery use is typically installed together with another application and that other application uses a lot of battery, then with such an embodiment (assuming that there is a good estimate for the battery use of that other application) the system would detect that the high battery usage observed from a device with both of the applications installed is expected because of the high battery usage of the other application and the system would therefore not wrongly “learn” that the first application has a high battery usage.

Embodiments of the invention are applicable to battery usage but can also be used for the effects on other properties of the device, such as the effect on the number of times that the device crashes, or re-boots, or the effect on any other disruptive events in respect of the device. In general, the system can for example analyse which program causes any of the following, by way of example:
Excessive battery usage, reboots, disruptions, wireless network data (Wi-Fi™) use, cellular data use, Bluetooth™ use, turning on of the screen and/or backlight, screen wear and/or hotspots, high battery temperature, high CPU use, high memory use, high storage use, application crashes, poor application performance and/or responsiveness, call hang-ups, the device to wake up, time and time zone changes, high numbers of notifications, the device to play sound, or the device to vibrate.

It will be appreciated that the monitoring application can monitor battery usage and/or one or more of the above listed events and these can be used separately to analyse the effect on different properties of the device or in combination to analyse the effect on a particular property.

In some embodiments of the invention, the programs considered are the operating system and installed applications. The operating system is treated like any other application. In some embodiments, a different version of the operating system or a different version of an installed application, counts as a different application for the purposes of analysis. In such cases the monitoring application provides not only identifiers for programs but also the version numbers of the programs.

In some embodiments of the invention, the monitoring data could include an exclusive identifier for the device on which the application is installed. However, this is not an essential requirement and it is sufficient to know which applications are installed on a device.

In some embodiments of the invention, when revising an existing estimate of the contribution of a program to the effect on the property of the devices, monitoring data from multiple devices can be processed in parallel by multiple processes accessing a joint data-storage, where each process can update estimates in the joint data-storage without blocking the operation of the other processes. Each process reads the old estimate from the joint data storage, computes an updated estimate and writes changes back to the joint data storage, without consideration to changes by other process that have taken place in the interim, thereby allowing the method to be scalable to process data from many devices, such as thousands, or millions of devices.

According to another aspect of the invention, there is provided a method of analysing the effect of programs on a property of a plurality of mobile data processing devices, wherein:

on each of those mobile devices there is installed a monitoring application which (i) analyses events relating to a property of the device (ii) determines the programs installed on the device and (iii) at intervals transmits to a server monitoring data which includes identifiers identifying programs installed on the device, and information concerning the property of the device;

on the server, the monitoring data from the plurality of devices is aggregated and estimates are obtained of the contribution of each program to the effect on the property of the devices;

subsequent monitoring data from the plurality of devices is aggregated and revised estimates are obtained, by machine learning techniques, of the contribution of each program to the effect on the property of the devices;

wherein, when revising an existing estimate of the contribution of a program to the effect on the property of the devices, an adaptive learning rate is used to determine how much weight to give new data relative to an existing estimate of the contribution of a program to the effect on the property of the devices, so that the learning rate is increased if it has been determined that the effect of the property of the device has been consistently under-estimated or over-estimated in the past.

According to another aspect of the invention, there is provided a method of analysing the effect of programs on a property of a plurality of mobile data processing devices, wherein:

on each of those mobile devices there is installed a monitoring application which (i) analyses events relating to a property of the device (ii) determines the programs installed on the device and (iii) at intervals transmits to a server monitoring data which includes identifiers identifying programs installed on the device, and information concerning the property of the device;

on the server, the monitoring data from the plurality of devices is aggregated and estimates are obtained of the contribution of each program to the effect on the property of the devices;

subsequent monitoring data from the plurality of devices is aggregated and revised estimates are obtained, by machine learning techniques, of the contribution of each program to the effect on the property of the devices;

wherein, when revising an existing estimate of the contribution of a program to the effect on the property of the devices, the weight given to new data is adapted so that greater weight is given to new data if it has been determined that the effect of the property of the device has been consistently under-estimated or over-estimated in the past.

According to another aspect of the invention, there is provided a method of analysing the effect of programs on a property of a plurality of mobile data processing devices, wherein:

on each of those mobile devices there is installed a monitoring application which (i) analyses events relating to a property of the device (ii) determines the programs installed on the device and (iii) at intervals transmits to a server monitoring data which includes identifiers identifying programs installed on the device, and information concerning the property of the device;

on the server, the monitoring data from the plurality of devices is aggregated and estimates are obtained of the contribution of each program to the effect on the property of the devices;

subsequent monitoring data from the plurality of devices is aggregated and revised estimates are obtained, by machine learning techniques, of the contribution of each program to the effect on the property of the devices;

wherein, when estimating the contribution of a program to the effect on the property of the devices, data is received and processed in respect of applications installed on a device, irrespective of the usage there has been of those applications.

According to another aspect of the invention, there is provided a method of analysing the effect of programs on a property of a plurality of mobile data processing devices, wherein:

on each of those mobile devices there is installed a monitoring application which (i) analyses events relating to a property of the device (ii) determines the programs installed on the device and (iii) at intervals transmits to a server monitoring data which includes identifiers identifying programs installed on the device, and information concerning the property of the device;

on the server, the monitoring data from the plurality of devices is aggregated and estimates are obtained of the contribution of each program to the effect on the property of the devices;

subsequent monitoring data from the plurality of devices is aggregated and revised estimates are obtained, by machine learning techniques, of the contribution of each program to the effect on the property of the devices;

wherein when revising an existing estimate of the contribution of a program to the effect on the property of the devices, the estimated contribution to the effect on the property of a particular device of all applications installed on that device is taken into account jointly.

According to another aspect of the invention, there is provided a method of analysing the effect of programs on a property of a plurality of mobile data processing devices, wherein:

on each of those mobile devices there is installed a monitoring application which (i) analyses events relating to a property of the device (ii) determines the programs installed on the device and (iii) at intervals transmits to a server monitoring data which includes identifiers identifying programs installed on the device, and information concerning the property of the device;

on the server, the monitoring data from the plurality of devices is aggregated and estimates are obtained of the contribution of each program to the effect on the property of the devices;

subsequent monitoring data from the plurality of devices is aggregated and revised estimates are obtained, by machine learning techniques, of the contribution of each program to the effect on the property of the devices; wherein:

when revising an existing estimate of the contribution of a program to the effect on the property of the devices, new data is used to revise the existing estimate rather than being combined with past data and the combined data being used to create a revised estimate; and/or

when a new observation is received by the server concerning the effect on the property of a particular device and a revised estimate is obtained of the contribution of each program to the effect on the property of the devices, all past observations are not used equally, but instead the last estimate is updated by the new observation; and/or

when revising an existing estimate of the contribution of a program to the effect on the property of the devices, an adaptive learning rate is used to determine how much weight to give new data relative to an existing estimate of the contribution of a program to the effect on the property of the devices, so that the learning rate is increased if it has been determined that the effect of the property of the device has been consistently under-estimated or over-estimated in the past; and/or

when revising an existing estimate of the contribution of a program to the effect on the property of the devices, the weight given to new data is adapted so that greater weight is given to new data if it has been determined that the effect of the property of the device has been consistently under-estimated or over-estimated in the past; and/or

wherein, when estimating the contribution of a program to the effect on the property of the devices, data is received and processed in respect of applications installed on a device, irrespective of the usage there has been of those applications; and/or

when revising an existing estimate of the contribution of a program to the effect on the property of the devices, the estimated contribution to the effect on the property of a particular device of all applications installed on that device is taken into account jointly.

According to another aspect of the invention, there is provided a method of analysing the effect of programs on a property of a plurality of mobile data processing devices, wherein:

on each of those mobile devices there is installed a monitoring application which (i) analyses events relating to a property of the device (ii) determines the programs installed on the device and (iii) at intervals transmits to a server monitoring data which includes identifiers identifying programs installed on the device, and information concerning the property of the device;

on the server, the monitoring data from the plurality of devices is aggregated and estimates are obtained of the contribution of each program to the effect on the property of the devices;

subsequent monitoring data from the plurality of devices is aggregated and revised estimates are obtained, by machine learning techniques, of the contribution of each program to the effect on the property of the devices;

wherein, when a new observation is received by the server concerning the effect on the property of a particular device and a revised estimate is obtained of the contribution of each program to the effect on the property of the devices, all past observations are not used equally, but instead the last estimate is updated by the new observation.

According to another aspect of the inventions, there is provided a method of analysing the effect of programs on a property of a plurality of mobile data processing devices, wherein:

on each of those mobile devices there is installed a monitoring application which (i) analyses events relating to a property of the device (ii) determines the programs installed on the device and (iii) at intervals transmits to a server monitoring data which includes identifiers identifying programs installed on the device, and information concerning the property of the device;

on the server, the monitoring data from the plurality of devices is aggregated and estimates are obtained of the contribution of each program to the effect on the property of the devices;

subsequent monitoring data from the plurality of devices is aggregated and revised estimates are obtained, by machine learning techniques, of the contribution of each program to the effect on the property of the devices;

wherein, multiple new observations are received by the server, each observation concerning the effect on the property of a particular device, and the multiple new observations are processed in parallel by multiple processes accessing joint data-storage, wherein each process reads an existing estimate from the joint data storage, computes an updated estimate and writes the updated estimate back to the joint data storage, without consideration to changes by other processes that have taken place in the interim.

Viewed from another aspect, the invention provides a method carried out on a server of analysing the effect of programs on a property of a plurality of mobile data processing devices each of which is in remote data communication with the server, wherein:

at intervals the server receives monitoring data from the devices, the monitoring data for each particular device including identifiers identifying programs installed on that particular device, and information concerning the property of that particular device;

on the server, the monitoring data from the plurality of devices is aggregated and estimates are obtained of the contribution of each program to the effect on the property of the devices;

subsequent monitoring data from the plurality of devices is aggregated and revised estimates are obtained, by machine learning techniques, of the contribution of each program to the effect on the property of the devices;

wherein:

when revising an existing estimate of the contribution of a program to the effect on the property of the devices, new data is used to revise the existing estimate rather than being combined with past data and the combined data being used to create a revised estimate; and/or

when a new observation is received by the server concerning the effect on the property of a particular device and a revised estimate is obtained of the contribution of each program to the effect on the property of the devices, all past observations are not used equally, but instead the last estimate is updated by the new observation; and/or

when revising an existing estimate of the contribution of a program to the effect on the property of the devices, an adaptive learning rate is used to determine how much weight to give new data relative to an existing estimate of the contribution of a program to the effect on the property of the devices, so that the learning rate is increased if it has been determined that the effect of the property of the device has been consistently under-estimated or over-estimated in the past; and/or

when revising an existing estimate of the contribution of a program to the effect on the property of the devices, the weight given to new data is adapted so that greater weight is given to new data if it has been determined that the effect of the property of the device has been consistently under-estimated or over-estimated in the past; and/or

wherein, when estimating the contribution of a program to the effect on the property of the devices, data is received and processed in respect of applications installed on a device, irrespective of the usage there has been of those applications; and/or

when revising an existing estimate of the contribution of a program to the effect on the property of the devices, the estimated contribution to the effect on the property of a particular device of all applications installed on that device is taken into account jointly.

The invention also extends to a tangible computer software product, for example in th form of instructions on a disk or on a solid state memory device, containing instructions for configuring a data processing machine in the form of a server to carry out the methods in accordance with the aspects of the invention.

### BRIEF DESCRIPTION OF THE DRAWINGS

Embodiments of the invention will now be described by way of example and with reference to the accompanying drawings, in which:

FIG. 1 is an overall schematic diagram of a system in accordance with the invention of devices communicating with a server;

FIG. 2 is a block diagram setting out basic steps carried out on a device;

FIG. 3 is a block diagram setting out basic steps carried out on the server;

FIG. 4A is the first part of pseudocode showing how an algorithm is used to put the invention into effect; and

FIG. 4B is the second part of the pseudocode.

### DETAILED DESCRIPTION OF PREFERRED EMBODIMENTS

The embodiments described in detail determine estimates for the amount of battery discharge caused by different applications. However the principles are applicable to determining other effects caused by application.

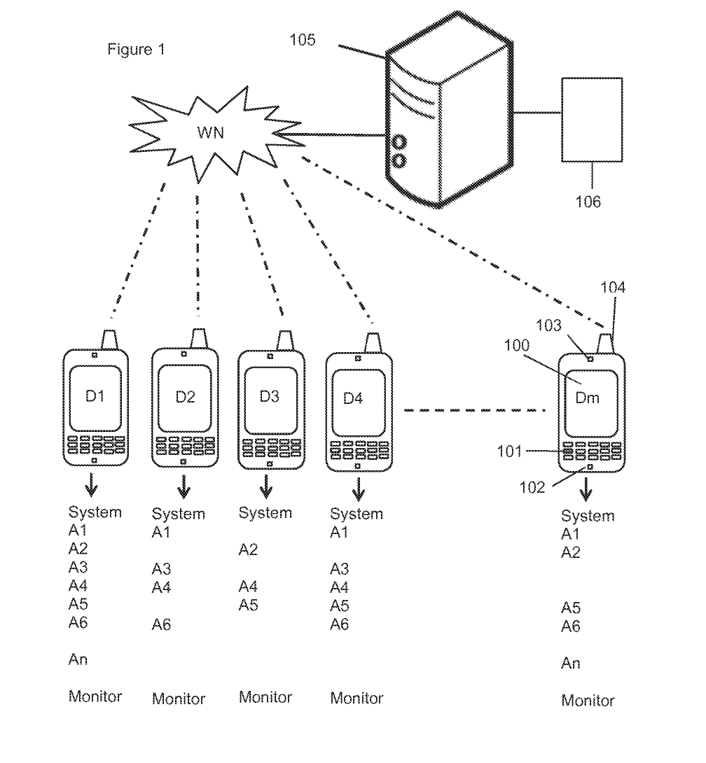

The system as illustrated in FIG. 1 comprises a number of battery powered mobile communications devices D1, D2, D3, D4 to Dm. Each of these devices has a screen 100, control buttons 101, a microphone 102, a loudspeaker 103 and an antenna 104 to communicate with a wireless communications network WN. The network may be, for example, a mobile communications network with data facilities such as a mobile phone network. The devices could also have other features, such as a bar code or similar code scanner, or a stylus used with a touch screen so that the recipient of an item can write a signature on the screen to acknowledge delivers. Also communicating with the network WN is a server 105, which may for example be connected to the network over a fixed land line. The devices D1 to Dm communicate data to the server 105, which carries out computations on the data, using various algorithms. It will be appreciated that the server could comprise a number of physical servers, over which the load is spread. This would be particularly advantageous if the number of devices is very large. In this embodiment the server 105 communicates with an external storage device 106 which could be, for example a single hard disk or a solid state bulk storage device, or an array of hard disks or solid state storage devices. The storage device could also be provided integrally within the server 105.

In addition to operating system applications installed on each device, indicated on FIG. 1 as “System”, there exists a number of n user applications A1 to An each of which can be installed on any subset of the m devices. Or in other words, there are m devices each of which can have any subset of the n user applications installed. In this embodiments, each version of an application is treated as an individual application. The aim is to characterise the battery discharge caused by individual applications, which could be represented by the mean μ and variance σ² of the battery discharge the application is causing. In addition there needs to be an estimate of an overall background battery discharge caused by the operating system applications. The expected battery discharge of a device c can then be simply modelled as the sum of the discharge caused by the applications installed on that device μ_{c} and the system usage μₛ.

These embodiments relate to obtaining estimates of battery usage per application that may be installed on a mobile device. A monitoring application “Monitor” is installed on each device and transmits data at intervals to the server 105, which carries out the calculations. In some embodiments the monitoring application checks at regular intervals, such as every 15 minutes, the current battery level and whether device is or is not being charged. From those samples, there is computed the average battery discharge of the device at less regular intervals, such as once a day. This average battery discharge is then submitted to the server, for example again once a day. The monitoring device also sends to the server information regarding which applications are installed on the device to the server, for example again once a day. In preferred embodiments of the invention, none of these actions, i.e. the collecting of information and the transmission of data, requires any action from a user of the device.

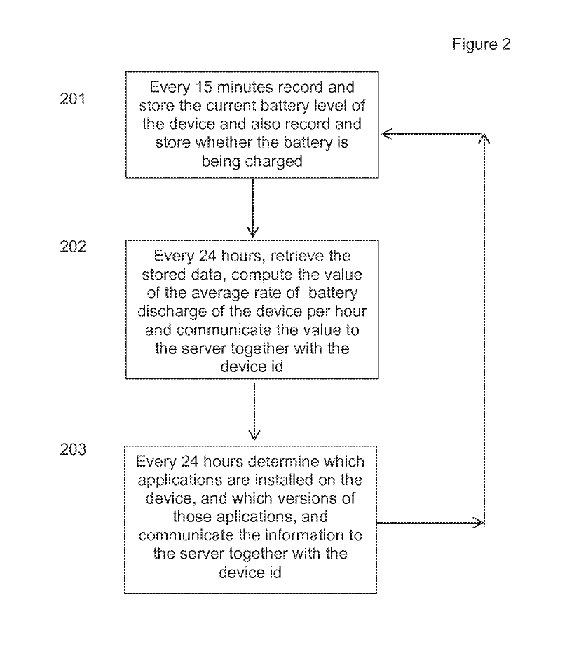

FIG. 2 shows the basic steps carried out by the monitoring application on a device, in block diagram form. At step 201, every 15 minutes the monitoring application records and stores the current battery level of the device and also records and stores whether the battery is being charged. At step 202, every 24 hours, the monitoring application retrieves the stored data, computes the value of the average rate of battery discharge of the device per hour and communicate the value to the server together with a unique id for the device. At step 203, every 24 hours the monitoring application determines which applications are installed on the device, and which versions of those applications, and communicates the information to the server together with the device id. The communication of data to the server in steps 202 and 203 may be done at the same time or on different occasions.

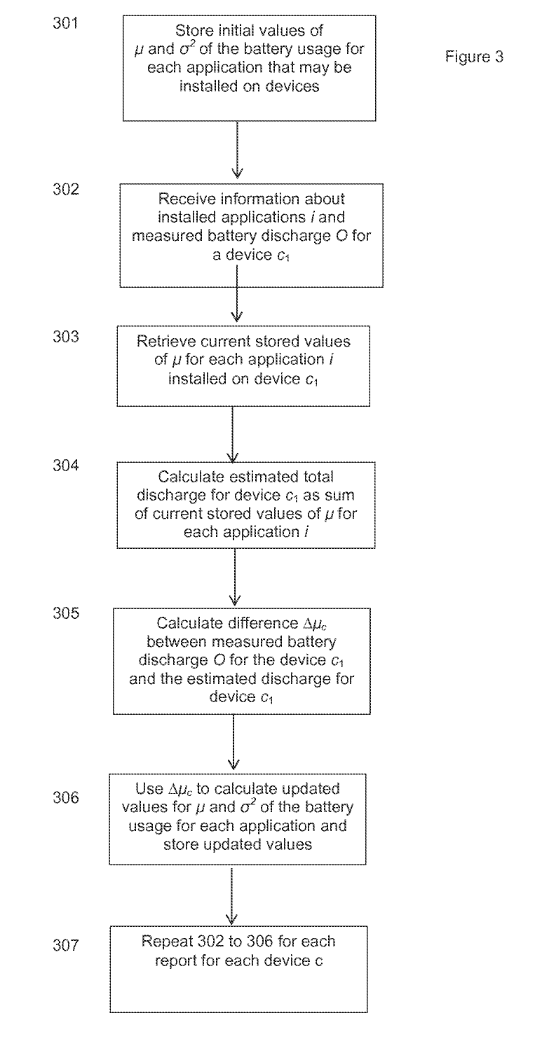

FIG. 3 shows the basic steps carried out by the server, in block diagram form. At step 301 a program stored on the server stores initial values of μ and σ² of the battery usage for each application that may be installed on devices. At step 302 the server receives information about installed applications i and measured battery discharge O for a device c₁. At step 303 the program retrieves current stored values of μ for each application i installed on device c₁. At step 304 the program calculates the estimated total discharge for device c₁ as sum of current stored values of μ for each application i. At step 305 the program calculates the difference Δμ_{c} between the measured battery discharge O for the device c₁ and the estimated discharge for device c₁. At step 306 the program uses Δμ_{c} to calculate updated values for μ and σ² of the battery usage for each application, using machine learning techniques, and stores updated values for use when subsequent reports are received from devices. At step 307, steps 302 to 306 are repeated for each subsequent report for each device c.

Dealing with what happens at the server end in more detail, when the server receives a daily discharge observation O(μ_{c}) from a device c, it is possible to compute the prediction error (i.e. by how much the daily discharge differs from what is expected given the applications Ac installed on the device) by computing Δμ_{c}=O(μ_{c})−(Σ_{i≢Ac}μᵢ+μₛ) where μᵢ is the battery discharge from the installed applications and μₛ is the battery discharge from the system. In order to update the estimates on the iεAc individual applications μᵢ (and μₛ) and σᵢ² (and σₛ²) it can be assumed that Δμ_{c} is a sum of Δμᵢ's, i.e. the overall error in the prediction is the sum of the errors of the predictions for each application and the system (Δμ_{c}=Σ_{iεAc}Δμᵢ+Δμₛ If there were known the individual Δμᵢ's, updating the estimates for μᵢ and σᵢ² would be fairly straightforward, however, as there are only observed the sums of the discharge, attributing the difference between expected and observed discharge to individual applications becomes more difficult. In this embodiment there is distributed part of the overall prediction error equally between all applications and the system and part of it according to the estimates of the variance. This distribution of the overall error is preferably additionally modulated by the confidence that the current estimate is correct. Using this method there is then an estimate for the “observed” per application discharge O(μᵢ)=μᵢ+Δμᵢ which is used to update the estimates of μᵢ and σi² weighting the new observation and the previous estimate according to the learning rate of the algorithm.

The core parameters to be estimated are the mean μ and the variance σ² of the battery usage caused by user applications and by the system. Different versions of an application are treated as different applications, i.e. it is necessary to store and access the current estimate of those two values for the system and every user application version installed on at least one device. As initial values for μ there is chosen something reasonable to help the learning algorithm to find the correct parameters in a reasonable time frame. A μ of 1 for the system and 0.02 for user applications might be an appropriate starting point in an implementation of an embodiment (the unit is percentage discharge per hour—which means the measure is relative to the quality of the battery). For the variance the initial value is set to something fairly large to express the uncertainty of the estimate. In one example it could be set to 16.

In addition to the parameters μ and σ² it would be useful to store the number of times there has been updated the estimate for a particular pair (μ, σ²), as this is another measure which says something about the reliability of the estimate and can be used in setting the learning rate. In addition there could be stored an adaptive learning rate parameter (called “momentum” below) for every application that reflects some information on how consistently there has been under- or over-estimated battery discharge recently.

Other than those values specific to this algorithm the algorithm depends on knowing the currently installed applications for the device that sends in a battery discharge report and the number of installs of those applications (if it is decided to make the learning rate dependent on the number of installs).

The input to the algorithm will then be an individual battery discharge report (device id; average percentage of discharge per hour for a day). For each update there is only needed access to the data of that device and the parameters and information for those applications installed on that device.

The algorithm (with the parameters as given below) is tailored to be able to learn changes in the battery usage of applications very rapidly (i.e. often within less than a day for reasonably frequent applications). This means if usage fluctuates over time (e.g. lower usage on the weekend) so will the estimate for the battery usage. It is considered that having the learning algorithm be that responsive to changes in usage would be useful, both to alert on newly installed disruptive applications early and because changes in usage over the time scale of days might actually be relevant information in some cases. However, this means in cases where it is desired to present the user with a more stable longer-term estimate of how much battery an application uses on average a mean estimate of the algorithm over a longer time span could be used (e.g. 14 days or a month).

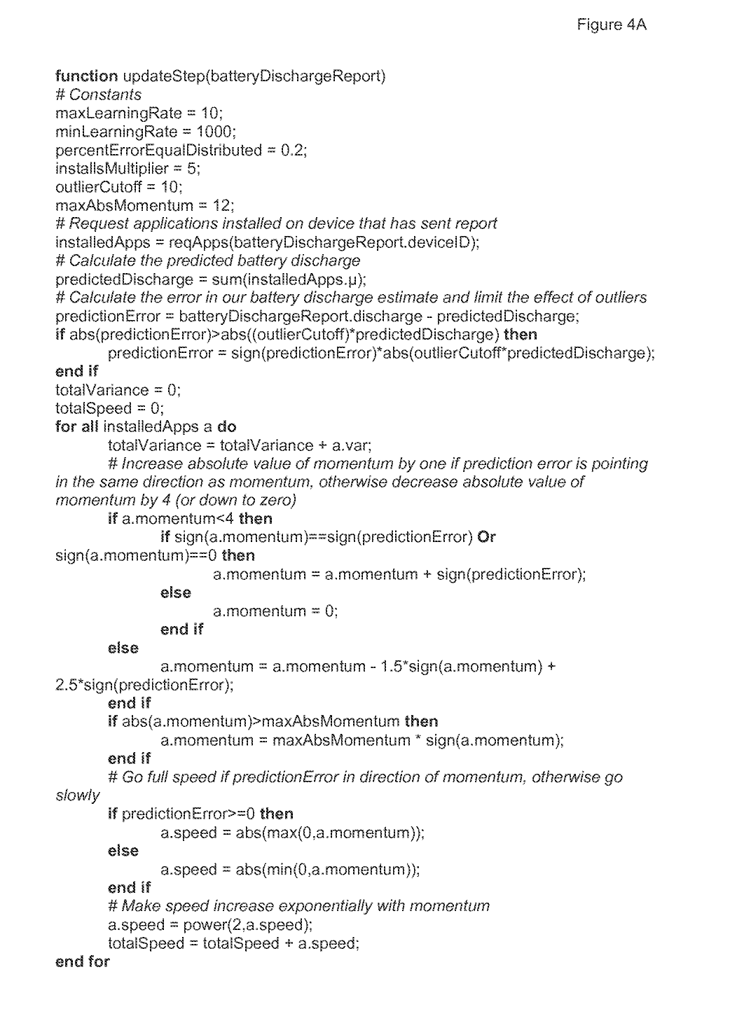

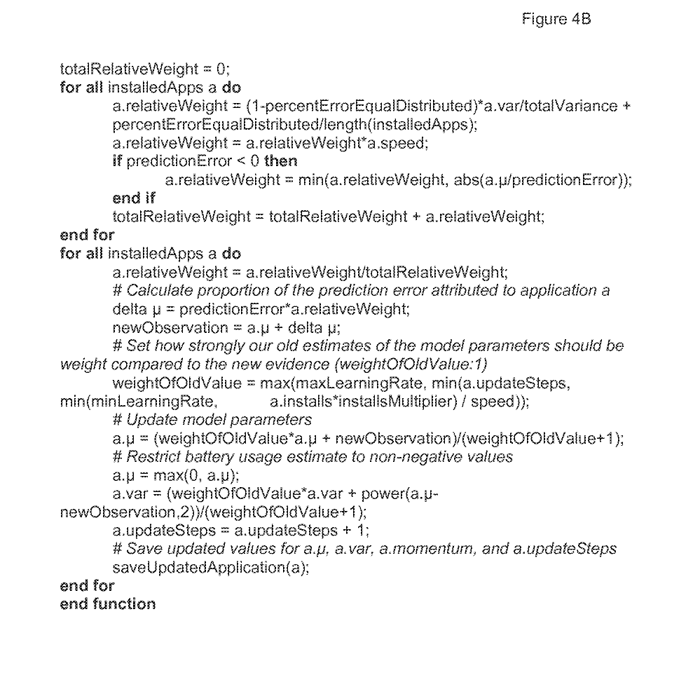

Each incoming daily battery discharge report triggers an update routine that takes the current battery discharge observation and uses it to update the estimates for the battery consumption of the system and the applications installed on the device. The pseudocode of FIGS. 4A and 4B outlines how that step could be implemented. System use is not treated any differently than user applications in the following, but is just treated as an application which is installed on all devices.

There will now be a discussion of some learning algorithm parameters

maxLearningRate and minLearningRate

maxLearningRate and minLearningRate set the bounds of how much influence a single observation can have on the results in relation to the weight given to old estimates. By changing those bounds it is possible to increase or decrease the minimum and maximum learning speed (a lower learning rate value means quicker learning). Very low values will mean that the algorithm will be quick in learning new values, but also that it will produce less stable results, fluctuate more and be more strongly impacted by outliers.

percentErrorEqualDistributed

percentErrorEqualDistributed allows one to tweak how stable one thinks the true battery discharge values are. If the battery use of applications was never changing, then a low value for this parameter would be good, as distributing the error by the estimate for the variance would be the most reasonable thing to do (at least if the initial values for the variance were reasonable). However, a low value can make unlearning a wrong value more difficult, as it means that there are made only small changes to values believed to have been well learnt. If the estimates are bad, either because of using untypical values initially or because the battery usage of an application has changed, than a higher value for this parameter helps the system to be more open-minded about which estimates are wrong and be quicker in correcting the error.

installsMultiplier

The installsMultiplier parameter controls how much quickly it is desired to update estimates for applications with fewer installs. If an application has very many installs there will be obtained many battery discharge observations on that application, which will allow the system to quickly learn the correct value while still not giving any individual update too much weight. If there are only a few installs, there will be a harder job to find the right balance between stability and speed of the estimates; setting this balance is essentially what this parameter does. Instead of using minLearningRate, applications with fewer installs will use their number of installs times installsMultiplier as their minimum learning rate.

outlierCutoff

outlierCutoff stabilises the results by limiting the effect of outliers. A value for outlierCutoff of 10 means the prediction error will be capped at 10 times the predicted discharge. In sample battery discharge data that has been analysed there is for example one battery discharge report that claims to have found a battery discharge of 755% per hour. If the predicted discharge of that device (based on the current estimates) was for example 2, this would mean that the prediction error would be 753. However, with an outlierCutoff of 10 this would be treated like an observation with a prediction error of 20 instead.

maxAbsMomentum

Setting a maximum for the momentum stops this value from growing without bounds in some extreme cases. Very large momentum terms need to be avoided as speed is exponentially related to momentum. Very large momentum terms can easily create numerical problems with values beyond machine precision. A value for maxAbsMomentum equal to 12 can be chosen for example, as that allows an application with full momentum to continue to learn with full speed as long as not more than every fifth prediction error goes against the momentum (i.e. minLeamingRate/2⁽¹²⁻⁴⁾ is still smaller than the maxLeamingRate), yet the momentum will still be quickly reduced down to zero as soon as the consistency in the prediction errors end.

### Discussion of the Momentum Term

The momentum represents a measure of how consistently there have been under- or over-estimated battery discharge for a particular application recently. If there are under- and overestimation of the battery discharge of an application about equally often, it means that the system has estimated the value reasonably well and can reduce the learning rate to refine the estimates rather than radically change them. If, however, the system continuously gets a prediction wrong in the same direction the estimate is probably further away from the true value and it is necessary to increase the size of the changes made. This mechanism allows the system to automatically adapt the learning rate when the incoming observations change and become inconsistent with the old estimates. A side effect of this mechanism is that the learning rate enhances the impact of update steps towards the median (rather than the mean). By going faster (for steps towards the median) when the system is wrong in the same direction more often than 50% of the time, and slower when the system is wrong in either direction about equally often, the learning rate biases the estimate towards a value that is closer to the median (i.e. somewhere between mean and median). Without this mechanism the algorithm would learn the mean value. This side effect can be a good thing (as the median is generally a more stable result that is more representative for most devices), but can also mean that the system is less likely to detect problems with high battery discharges in only a (smaller) subset of the devices (as problems with a smaller subgroup will show up more strongly in the mean than the median). Whether this effect is desirable or not therefore depends on the specific question one tries to answer. In this embodiment the current proposal strikes a good balance that gives meaningful estimates, but it is worth keeping that issue in mind. It should be considered when communication of the value that is estimated; the system does not estimate the mean/average discharge an application is causing, but maybe more vaguely its “typical” discharge rate.

There will now be discussed some simplifications which can be used in some embodiments of the invention.

updateSteps

The purpose of the updateSteps counter is to initially use a higher learning rate for new applications to converge more quickly to the true value. With the adaptive learning rate, mediated by the momentum term, this additional modifier to the learning rate might not be really necessary, as the momentum should increase the learning speed if the initial estimate for a new application is bad. However, storing the number of update steps is probably a good idea anyway, as it is another metric that allows the system to gauge how well it has already estimated the parameters. When creating alerts on high battery discharge estimates, the system might only want to consider applications with a minimum number of update steps.

Variance and percentErrorEqualDistributed

Instead of measuring the variance of applications and distributing the prediction error on applications accordingly, the system could also simply equally distribute 100% of the error (equivalent to a percentErrorEqualDistributed value of 1). In that case the learning rate could probably be decreased (increase the value for minLearningRate), and the system would rely more strongly on momentum to adapt the learning rate for different applications. However, the estimate for the variance might in itself be a value one is interested in, and adjusting learning rate parameters might become more difficult without it.

Number of installs and installsMultiplier

The process could make the learning rate independent of the number of times an application is installed across the body of devices. If this was done the process would increase the stability of the estimates for applications with fewer installs for the cost of a (much) slower learning of the best estimates for those. Instead of or in addition to using the number of installs to modify the learning rate, it could also be modified by the number of daily updates that are received for an application. This latter measure would be more meaningful in case there are large number of devices that do not send updates regularly.

In the algorithm as described above, the estimates are restricted to always be non-negative, i.e. the system does not allow any application to “save battery” by being installed on a device. Making this restriction makes the problem easier in some cases. In the case where two applications are installed on nearly the same set of devices it could otherwise happen that the system gets into a cycle where it correctly predicts the overall battery usage of those devices, but this is done by increasingly overestimating the use of the one application and increasingly underestimating the use of the other application. When estimates are bound on the lower end, there is thereby automatically also prevented the estimates from growing out of bound at the higher end.

Alternatively, it would be possible also to allow negative values, but bound the growth of estimates for very low (battery saving) and very large (battery killing) battery usage estimates by favouring updates towards zero compared to updates away from zero. Allowing negative values is appealing from a modelling perspective, as introducing a fixed minimum is always to some extend arbitrary. It could, for example, be useful to detect that if, say, the mobile Opera™ browser uses less resources than, for example, a pre-installed Chrome™ browser that users installing Opera could actually save battery. Applications that change the system behaviour (e.g. turn off network connectivity if not needed) in order to save battery would be expected to show negative battery usage even more directly. On the other hand, it is known that an application does not literally use a negative amount of battery. Having negative battery use estimates would likely make the results more difficult to understand by users, i.e. negative results could be perceived as a wrong/unreliable estimate, rather than a useful feature of the system.

When there is received a battery discharge report that has been raised much earlier, it should probably not be used to update the estimates. The algorithm is aimed at updating a current estimate without revisiting old data. However the system could still use an older battery discharge report to update a current estimate, if it is considered still valid and it may be acceptable to use occasionally older estimates. However, if old reports are allowed, there could be large numbers of them at once, e.g. if a device (or a whole group of devices) has been out of contact for a couple of months and then re-establishes a connection, it could send in a large number of old reports within a short period of time. It may be wise to not use battery discharge reports raised more than 24 hours ago (or a few days at most).

Embodiments of the present invention can be used for a wide range of mobile devices running various operating systems such as Android™, iOS™ from Apple™, Microsoft™ Windows™ and older operating systems such as Windows CE™. Whist some modern versions of for example the Android operating system may provide data regarding individual battery usage of applications, embodiments of the present invention will provide useful information which is not available from that basic data regarding individual applications. The system in accordance with the invention does not require user intervention and can provide useful information to businesses which provide the mobile devices to users for use on company business.

Embodiments of the invention analyse the data received from the monitoring applications on a large number of devices, which may be thousands, and the system analyses the data using machine learning techniques and statistical techniques. An estimate can be provided as to the amount of battery usage different programs cause when installed on a device, be they the operating system or installed applications.

In accordance with some embodiments of the various aspects of the invention, there is provide a method for analysing the effect of installed applications on battery usage of mobile communications devices. Each device has monitoring software which monitors battery usage at frequent intervals throughout the day. The monitoring software calculates the average battery discharge and at less frequent intervals, such as once a day, communicates remotely to a server the details of which applications are installed on the device and the details of the state of the battery. Using data from many devices, the server estimates the effect of each application on battery usage. The estimated effects of the applications are updated each time that a further report is received, by revising the existing estimate. Greater weight is given to new data if the effect on battery usage has been consistently over- or under-estimated. It is not necessary to determine whether a particular application has been used. The effect of all applications installed on a device is taken into account jointly. The effect on properties other than battery usage can be determined using this method.

Reports can be produced setting out the estimated effects of programs on properties of devices, such as battery usage for different programs and/or notifications can be provided if there is a potential excessive effect, such as excessive battery usage.

It will be appreciated that where there are references to battery usage in this specification, the features concerned are applicable to other properties of the device also.

The embodiments of the invention are exemplary only and those skilled in the art will appreciate that variations and modifications may be made, without departing form the true spirit and scope of the invention as defined in the appended claims.

What is claimed is:

1. A method of analysing the effect of programs on the battery usage of a plurality of mobile, battery powered, data processing devices, wherein:
on each of those mobile devices there is installed a monitoring application which (i) analyses events relating to battery usage of the device (ii) determines the programs installed on the device and (iii) at intervals transmits monitoring data to a server over a wireless communications network, the monitoring data including identifiers identifying programs installed on the device, and information concerning the battery usage of the device;
on the server, the monitoring data from the plurality of devices is aggregated and estimates are obtained of the contribution of each program to the effect on battery usage of the devices;
subsequent monitoring data from the plurality of devices is aggregated and revised estimates are obtained, by machine learning techniques, of the contribution of each program to the effect on battery usage of the devices;
wherein, when a new observation is received by the server concerning the effect on battery usage of a particular device and a revised estimate is obtained of the contribution of each program to the effect on the battery usage of the devices, all past observations are not used equally, but instead the last estimate is updated by the new observation.

2. A method as claimed in claim 1 wherein, when estimating the contribution of a program to the effect on battery usage of the devices, the estimated contribution to the effect on battery usage of a particular device of all applications installed on that device is taken into account jointly.

3. A method as claimed in claim 1 wherein monitoring data from multiple devices is processed in parallel by multiple processes accessing joint data-storage, wherein each process reads an existing estimate of the contribution of a program to the effect on battery usage of the device from the joint data storage, computes an updated estimate and writes the updated estimate back to the joint data storage, without consideration to changes by other processes that have taken place in the interim.

4. A method as claimed in claim 1 wherein, when revising an existing estimate of the contribution of a program to the effect on battery usage of the devices, the weight given to new data is adapted so that greater weight is given to new data if it has been determined that the effect on battery usage of the device has been consistently under-estimated or over-estimated in the past.

5. A method as claimed in claim 4 wherein an adaptive learning rate is used to determine how much weight to give new data relative to an existing estimate of the contribution of a program to the effect on battery usage of the device, so that the learning rate is increased if it has been determined that the effect of the property of the devices has been consistently under-estimated or over-estimated in the past.

6. A method as claimed in claim 1 wherein, when estimating the contribution of a program to the effect on battery usage of the devices, data is received and processed in respect of applications installed on a device, irrespective of the usage there has been of those applications on that device.

7. A method of analysing the effect of programs on a property of a plurality of mobile data processing devices, wherein:
on each of those mobile devices there is installed a monitoring application which (i) analyses events relating to a property of the device (ii) determines the programs installed on the device and (iii) at intervals transmits to a server monitoring data which includes identifiers identifying programs installed on the device, and information concerning the property of the device;
on the server, the monitoring data from the plurality of devices is aggregated and estimates are obtained of the contribution of each program to the effect on the property of the devices;
subsequent monitoring data from the plurality of devices is aggregated and revised estimates are obtained, by machine learning techniques, of the contribution of each program to the effect on the property of the devices;
wherein
when revising an existing estimate of the contribution of a program to the effect on the property of the devices, new data is used to revise the existing estimate rather than being combined with past data and the combined data being used to create a revised estimate.

8. A method as claimed in claim 7 wherein, when estimating the contribution of a program to the effect on the property of the devices, the estimated contribution to the effect on the property of a particular device of all applications installed on that device is taken into account jointly.

9. A method as claimed in claim 7 wherein monitoring data from multiple devices is processed in parallel by multiple processes accessing joint data-storage, wherein each process reads an existing estimate from the joint data storage, computes an updated estimate and writes the updated estimate back to the joint data storage, without consideration to changes by other processes that have taken place in the interim.

10. A method as claimed in claim 7 wherein, when revising an existing estimate of the contribution of a program to the effect on the property of the devices, the weight given to new data is adapted so that greater weight is given to new data if it has been determined that the effect of the property of the device has been consistently under-estimated or over-estimated in the past.

11. A method as claimed in claim 10 wherein an adaptive learning rate is used to determine how much weight to give new data relative to an existing estimate of the contribution of a program to the effect on the property of the device, so that the learning rate is increased if it has been determined that the effect of the property of the devices has been consistently under-estimated or over-estimated in the past.

12. A method as claimed in claim 7 wherein, when estimating the contribution of a program to the effect on the property of the devices, data is received and processed in respect of applications installed on a device, irrespective of the usage there has been of those applications on that device.

13. A method as claimed in claim 7, wherein the devices are battery powered and the property of the devices comprises battery usage.

14. A method as claimed in claim 7 wherein the devices are in communication with a wireless communications network.

15. A method carried out on a server of analysing the effect of programs on a property of a plurality of mobile data processing devices each of which is in remote data communication with the server, wherein:
at intervals the server receives monitoring data from the devices, the monitoring data for each particular device including identifiers identifying programs installed on that particular device, and information concerning the property of that particular device;
on the server, the monitoring data from the plurality of devices is aggregated and estimates are obtained of the contribution of each program to the effect on the property of the devices;
subsequent monitoring data from the plurality of devices is aggregated and revised estimates are obtained, by machine learning techniques, of the contribution of each program to the effect on the property of the devices;
wherein, when revising an existing estimate of the contribution of a program to the effect on the property of the devices, new data is used to revise the existing estimate rather than being combined with past data and the combined data being used to create a revised estimate.

16. A method as claimed in claim 15, wherein when estimating the contribution of a program to the effect on the property of the devices, the estimated contribution to the effect on the property of a particular device of all applications installed on that particular device is taken into account jointly.

17. A method as claimed in claim 15 wherein monitoring data from multiple devices is processed in parallel by multiple processes accessing joint data-storage, wherein each process reads an existing estimate from the joint data storage, computes an updated estimate and writes the updated estimate back to the joint data storage, without consideration to changes by other processes that have taken place in the interim.

18. A method as claimed in claim 15 wherein, when revising an existing estimate of the contribution of a program to the effect on the property of the devices, the weight given to new data is adapted so that greater weight is given to new data if it has been determined that the effect of the property of the device has been consistently under-estimated or over-estimated in the past.

19. A method as claimed in claim 15 wherein an adaptive learning rate is used to determine how much weight to give new data relative to an existing estimate of the contribution of a program to the effect on the property of the device, so that the learning rate is increased if it has been determined that the effect of the property of the devices has been consistently under-estimated or over-estimated in the past.

20. A method as claimed in claim 15, wherein the devices are battery powered and the property of the devices comprises battery usage.
